(19) United States
(12) Patent Application Publication
(10) Pub. No.: US 2013/0269762 A1
(43) Pub. Date: Oct. 17, 2013

(54) CORE-SHELL NANOSTRUCTURE BASED PHOTOVOLTAIC CELLS AND METHODS OF MAKING SAME

(71) Applicant: BOARD OF TRUSTEES OF THE UNIVERSITY OF ARKANSAS, Little Rock, AR (US)

(72) Inventor: Jingbiao Cui, Little Rock, AR (US)

(73) Assignee: Board of Trustees of the University of Arkansas, Little Rock, AR (US)

(21) Appl. No.: 13/863,800

(22) Filed: Apr. 16, 2013

Related U.S. Application Data
(60) Provisional application No. 61/624,854, filed on Apr. 16, 2012.

(51) Int. Cl. H01L 31/0352; H01L 31/18

(52) U.S. Cl. CPC H01L 31/035236; H01L 31/18
USPC 136/255; 438/57

(57) ABSTRACT

A photovoltaic cell includes nanostructures formed of nanowires on a substrate, where the nanostructures include an array of three dimensional nanotrees or nanobushes with a core-shell structure having a core and one or more shells sequentially formed on the core. The core o f the core-shell structure is formed of a highly conductive metal or semiconductor, and the shell o f the core-shell structure is formed of a metal, semiconductor, or polymer, such that the core-shell structure has substantially large surface and interface area for photon energy harvesting and conversion into electricity.

### CROSS-REFERENCE TO RELATED PATENT APPLICATIONS

This application claims priority to and the benefit of, pursuant to 35 U.S.C. §119(e), U.S. provisional patent application Ser. No. 61/624,854, filed Apr. 16, 2012, entitled “SOLAR CELLS COMPRISING HIERARCHICAL CORE-SHELL NANOSTRUCTURES, AND METHODS OF MAKING SAME,” by Jingbiao Cui, the disclosure of which is incorporated herein in its entirety by reference.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

### STATEMENT AS TO RIGHTS UNDER FEDERALLY-SPONSORED RESEARCH

This invention was made with government support under grant number EPS-1003970 awarded by the National Science Foundation. The government has certain rights in the invention.

### FIELD OF THE INVENTION

The invention relates generally to energy conversion, and more particularly to core-shell nanostructure based photovoltaic cells and methods of making same.

### BACKGROUND OF THE INVENTION

Cost of fabrication and unsatisfied energy conversion efficiency are the two main obstacles that limit the wide applications of solar cells. Solar cells' cost-per-watt is a critical factor that determines whether a particular solar cell technology will be transitioned from the research laboratory to commercialization. In order to achieve high efficiency, tremendous research work has been done in the last decades. However, efficiency improvements are often accompanied by complex structures with high fabrication costs.

One of the important thrusts in solar cell research is to improve solar cell performance by using nanomaterials with an expectation of reducing the critical cost-per-watt ratio. The nanowire (NW) geometry provides potential advantages over planar thin-film solar cells. Currently, there exist commonly explored NW solar cell structures including NW axial junctions, NW radial junctions, and NWs embedded in thin films. The axial junction NW solar cells are not expected to have high efficiency due to the small junction area and less materials for light absorption.

For the radial junction NW structures, various inorganic NW solar cells based on Si, GaN, CdS, ZnO, CdTs, and GaAs have been experimentally demonstrated. One typical radial junction NW solar cells is based on core-shell structures of both single NWs and NW arrays. Si has been widely used in the current solar market, and its NW version has also been investigated. For example, individual Si NW core-shell structures, consisting of a p-type core with intrinsic and n-type shells, were fabricated and an energy conversion efficiency of 3.4% was obtained for the Si NW core-shell structures. Other materials such as GaAs core-shell structures have also be fabricated as radial junction solar cells, with an energy conversion efficiency of 4.5% observed.

In order to have practical application potential, large vertically aligned NW arrays are needed for NW solar cell fabrication. There are certain technical challenges to fabricate NW core-shell arrays due to the difficulty in shell material filtration into the core arrays and fabrication of electrical contacts. Large area arrays of Si radial p-n junctions were fabricated, where crystalline Si was etched to form arrays of n-type Si NW cores and then deposited p-type polycrystalline Si shells. An overall efficiency of 0.46% was obtained.

For the embedded NW radial junction structure, the use of inorganic NWs as charge collectors in dye-sensitized solar cells has been studied. However, there is no report on embedded core-shell NW arrays in inorganic thin films for PV applications, due to the difficulty of filling the gaps between NWs with thin films in vacuum deposition. NW solar cells with efficiencies up to 6% were demonstrated by using CdS NW arrays embedded in CdTe thin films in which CdS NWs were used with exposed length comparable to the distance between NWs, making it possible to deposit CdTe into the gaps by vapor deposition. It was found that the solar cell efficiency increased with the increase of embedded NW height due to the increased junction area. However, it is difficult to make NW radial junctions when the NWs are dense and long.

Therefore, a heretofore unaddressed need exists in the art to address the aforementioned deficiencies and inadequacies.

### SUMMARY OF THE INVENTION

One of the objectives of the invention is to provide radial junction structures applicable for NW photovoltaic (PV) cells with high efficiency, so as to overcome the limiting factor of short carrier lifetime in absorber and insufficient charge collection through NWs. In order to lower the fabrication cost, economic elements and cheap processes are used for the fabrication of the NW radial junction structures. The further enhanced surface areas and light confinement help elucidate the role of interfaces played in charge separation and collection.

The efficiency of a PV cell or device depends on the amount of light absorbed and the subsequent collection of the generated carriers. The NW structures with radial p-n junctions offer a number of advantages for PV applications as compared to their planar and other NW structures: (1) The NW arrays help reduce surface light reflection; (2) The three dimensional geometric structure can have light trapping properties, which help increase the light absorption; (3) The radial junctions can significantly enhance the p-n junction area and increase the charge separation probability; (4) the NWs can provide charge collection electrodes, which reduce carrier collection length. In addition to these benefits, other advantages include improved band gap tuning for absorption in desired wavelength, increased defect tolerance in materials, and reduced quantity of material necessary to approach high efficiency and economic fabrication.

In one aspect of the invention, a PV cell includes nanostructures formed of nanowires on a substrate, where the nanostructures include three dimensional (3D) nanotrees or nanobushes.

In one embodiment, each nanotree or nanobush has a plurality of branches and a plurality of subbranches grown from the plurality of braches. In another embodiment, each nanotree or nanobush has one or more trunks from which the plurality of branches grows. All the one or more trunks, the plurality of branches and the plurality of subbranches are formed with a core-shell structure.

The core-shell structure includes a core and a shell formed on and covering the core.

In one embodiment, the diameter of the core of the core-shell structure is around tens to hundreds nanometers, and the thickness of the shell of the core-shell structure is about from a few nanometers to hundred nanometers. In one embodiment, the height of the nanotrees or nanobushes is about a few micrometers to tens or hundreds micrometers.

In one embodiment, the core and shell of the core-shell structure are formed of the same or different semiconductor or metal materials.

In one embodiment, the core of the core-shell structure is formed of a highly conductive metal or semiconductor, and the shell o f the core-shell structure is formed of a metal, semiconductor, or polymer, such that the core-shell structure has substantially large surface and interface area for photon energy harvesting and conversion into electricity.

In one embodiment, the shell of the core-shell structure is formed of active materials with superior photochemical and sensing properties, and the core of the core-shell structure is formed of a highly conductive material for charge transfer and collection.

In one embodiment, the core of the core-shell structure is formed of an n-type wideband semiconductor, and the shell is formed of a p-type organic or inorganic thin layer for visible and near IR light absorption.

In one embodiment, the shell is formed of a semiconductor including TiO2, Si, CdS, CdTe, CIGS, or the like.

In one embodiment, the core-shell structure further includes a core, a first shell formed on and covering the core, and a second shell formed on and covering the first shell. The core is formed of a metal or semiconductor as a support backbone, the first shell is formed of a p-type or an n-type semiconductor and the second shell is formed of an n-type or a p-type semiconductor so that a p-n junction is formed between the first shell and the second shell. In one embodiment, the first/second shells include n-Si/p-Si, n-CdS/p-CdTe, n-CdS/p-CIGS, or the like.

In one embodiment, the substrate is formed of an electrically conductive material, and transparent to light.

In one embodiment, the photovoltaic cell further includes an electrode formed of an electrically conductive material on the nanostructures such that the nanostructures are located between the substrate and the electrode.

In another aspect of the invention, a method for making a photovoltaic cell having an array of 3D nanotrees or nanobushes with a core-shell structure, includes the steps of growing nanowires on a substrate to form a core of the core-shell structure for defining the array of 3D nanotrees or nanobushes thereon; and coating a first thin layer on the core of the core-shell structure to form a shell of the core-shell structure.

In one embodiment, the growing step is performed by electrochemical deposition in solution.

In one embodiment, the coating step is performed by chemical vapor deposition, atomic layer deposition, electrochemical deposition, or the like.

In one embodiment, each nanotree or nanobush has a plurality of branches and a plurality of subbranches grown from the plurality of braches. In one embodiment, each nanotree or nanobush has one or more trunks from which the plurality of branches grows.

In one embodiment, the core and shell of the core-shell structure are formed of the same or different semiconductor or metal materials.

In one embodiment, the core of the core-shell structure is formed of a highly conductive metal or semiconductor, and the shell o f the core-shell structure is formed of a metal, semiconductor, or polymer, such that the core-shell structure has substantially large surface and interface area for photon energy harvesting and conversion into electricity.

In one embodiment, the shell of the core-shell structure is formed of active materials with superior photochemical and sensing properties, and the core o f the core-shell structure is formed of a highly conductive material for charge transfer and collection.

In one embodiment, the core of the core-shell structure is formed of an n-type wideband semiconductor, and the shell is formed of a p-type organic or inorganic thin layer for visible and near IR light absorption.

In one embodiment, the method further includes the step of coating a second thin layer on the thin layer first thin layer to form a double shell of the core-shell structure. The core is formed of a metal or semiconductor as a support backbone, the first shell is formed of a p-type or an n-type semiconductor and the second shell is formed of an n-type or a p-type semiconductor so that a p-n junction is formed between the first shell and the second shell.

In another embodiment, the method further includes the step of coating one or more thin layers on the first thin layer to form multiple shells of the core-shell structure, wherein the core is formed of a metal or semiconductor as a support backbone, the first thin layer and the one or more thin layers are formed of different semiconductors such that a p-n junction is formed at an interface between any two adjacent thin layers.

In yet another aspect of the invention, a photovoltaic cell has a substrate; at least one thin film formed on the substrate, where the at least one thin film defines a plurality of recesses therein; and an electrode formed of nanowires on the at least one thin film such that the electrode has a thin layer and an nanowire array extending from the thin layer into the plurality of recesses of the at least one thin film.

In one embodiment, the nanowire array includes a core-shell structure having a core and at least one shell formed on and covering the core.

In one embodiment, the outer shell of the core-shell structure of the nanowire array is formed of an n-type or a p-type semiconductor.

In one embodiment, the at least one thin film is formed of a p-type or an n-type semiconductor, so that the outer shell of the core-shell structure of the nanowire array and the at least one thin film define a p-n junction therebetween.

In one embodiment, the at least one thin film includes a first thin film and a second thin film stacked on the substrate. The second thin film is formed of a p-type or an n-type semiconductor, so that the outer shell of the core-shell structure of the nanowire array and the second thin film define a p-n junction therebetween.

In one embodiment, the at least one thin film further includes a buffer film formed on the second thin film.

In one embodiment, the core of the core-shell structure of the nanowire array is formed of a substantially high conductive material for charge collection.

In one embodiment, the at least one thin film is formed to be a semiconductor light absorber.

In one embodiment, the at least one thin film is formed of be a p-type or an n-type CIGS, CZTS, CdS, CdTe, Cu₂O, Si, or the like.

In a further aspect, the invention relates to a photovoltaic device comprising one or more photovoltaic cells as disclosed above.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows schematically a nanoforrest of nanotrees or nanobushes, forming a two-dimensional (2D) array on a substrate, according to one embodiment of the present invention.

FIG. 2 shows schematically a PV cell structure with a bottom window and a back contact according to one embodiment of the present invention.

FIG. 3 shows schematically (a) a nanotree, and (b) a cross-sectional view of a nanotree according to one embodiment of the present invention.

FIG. 4 shows schematically a cross-sectional view of branches of a nanotree according to one embodiment of the present invention. All the branches have core-shell structures.

FIG. 5 shows schematically a cross-sectional view of a core-shell structure of the branches with a single shell according to one embodiment of the present invention.

FIG. 6 shows schematically a cross-sectional view of a core-shell of the branches with a double-shell according to one embodiment of the present invention.

FIG. 7 shows (a) an SEM image of nanotrees or nanobushes according to one embodiment of the present invention, and (b) an SEM image of nanotrees or nanobushes according to another embodiment of the present invention.

FIG. 8 shows (a) an SEM image and (b) a TEM image of a core-shell structure of nanotrees according to one embodiment of the present invention. The TEM image shows the core-shell structure: the central part is the nanowire core and the outer part is the nanowire shell. The shell thickness is about 10 nanometers and the core diameter is about 50 to 60 nanometers.

FIG. 9 shows schematically a PV cell having an NW array embedded in thin films according to one embodiment of the present invention.

FIG. 10 shows schematically a PV cell having an NW array embedded in thin films according to another embodiment of the present invention.

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top”, may be used herein to describe one element's relationship to another element as illustrated in the

Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower” can, therefore, encompass both an orientation of “lower” and “upper”, depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about”, “substantially” or “approximately” shall generally mean within 20 percent, preferably within 10 percent, and more preferably within 5 percent of a given value or range. Numerical quantities given herein are approximate, meaning that the term “around”, “about”, “substantially” or “approximately” can be inferred if not expressly stated.

As used herein, the terms “comprise” or “comprising”, “include” or “including”, “carry” or “carrying”, “has/have” or “having”, “contain” or “containing”, “involve” or “involving” and the like are to be understood to be open-ended, i.e., to mean including but not limited to.

As used herein, the phrase “at least one of A, B, and C” should be construed to mean a logical (A or B or C), using a non-exclusive logical OR. It should be understood that one or more steps within a method may be executed in different order (or concurrently) without altering the principles of the invention.

As used herein, a “nanostructure” refers to an object of intermediate size between molecular and microscopic (micrometer-sized) structures. In describing nanostructures, the sizes of the nanostructures refer to the number of dimensions on the nanoscale. For example, nanotextured surfaces have one dimension on the nanoscale, i.e., only the thickness of the surface of an object is between 1.0 and 1000.0 nm. Nanowires have two dimensions on the nanoscale, i.e., the diameter of the tube is between 1.0 and 1000.0 nm; its length could be much greater. Finally, sphere-like nanoparticles have three dimensions on the nanoscale, i.e., the particle is between 1.0 and 1000.0 nm in each spatial dimension. A list of nanostructures includes, but not limited to, nanoparticle, nanocomposite, quantum dot, nanofilm, nanoshell, nanofiber, nanowire, nanotree, nanobush, nanotube, nanoring, nanorod, and so on.

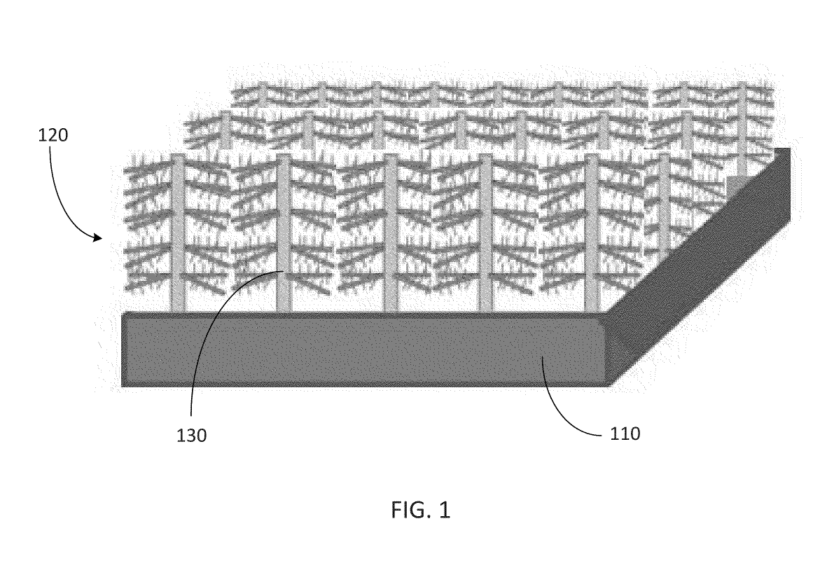

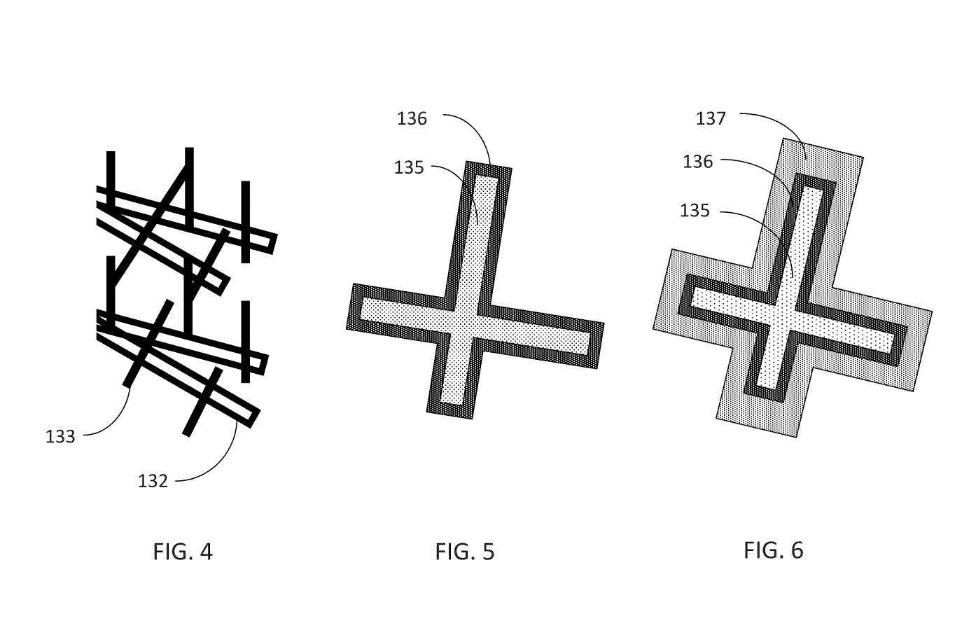

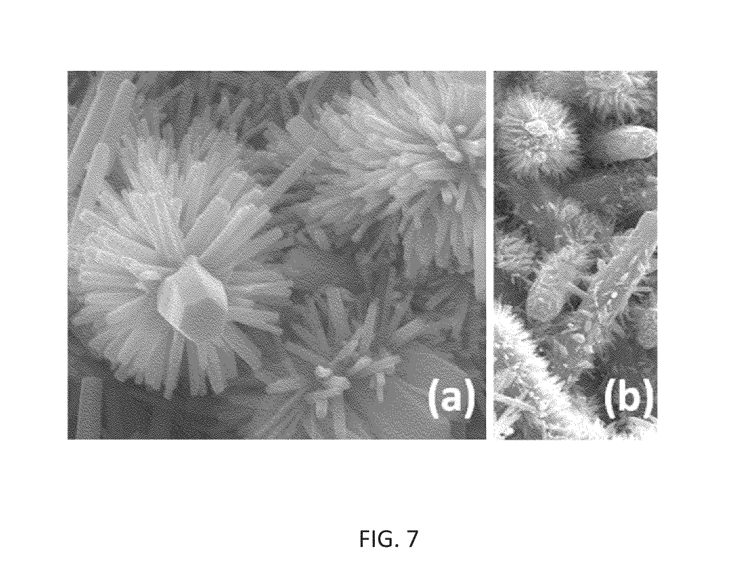

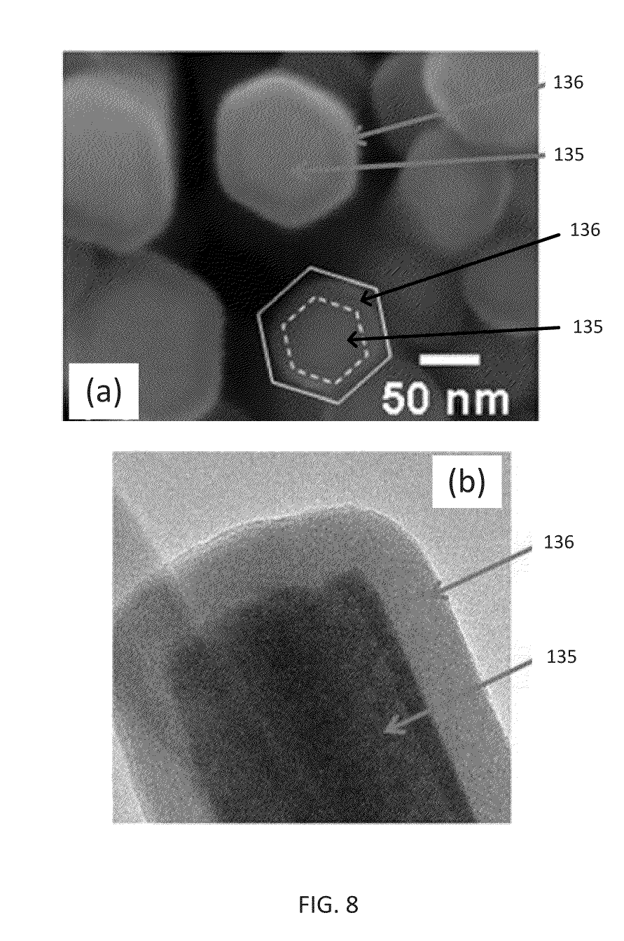

The description is now made as to the embodiments of the invention in conjunction with the accompanying drawings of FIGS. 1-10. In accordance with the purposes of this invention, as embodied and broadly described herein, this invention relates to a PV cell that is based on innovative hierarchical core-shell nanostructures of nanowires.

The nanowire (NW) geometry provides potential advantages over planar thin-film PV cells. For example, the high surface-to-volume ratio and high conductivity of nanowires are expected to improve charge separation and collection. Although the output efficiencies have steadily increased over the years, the achieved laboratory cell efficiency of nanowire PV cells is still far from satisfactory. Several challenges still need to be addressed in order to achieve high efficiency at low cost. The observed low efficiencies for nanowire PV cells may be associated with the weak absorption of the thin nanowires, poor interface quality, and low conductivity of the nanowires used. In order to improve the cell efficiency, it's important to increase the light absorption, and charge separation and collection. In on embodiment, this invention provides a PV cell structure using innovative three-dimensional (3D) hierarchical core-shell nanostructures of nanowires, such as nanotrees or nanobushes, to achieve a high efficiency at low cost. The unique structure is also potentially useful for highly sensitive sensors and detectors and so on.

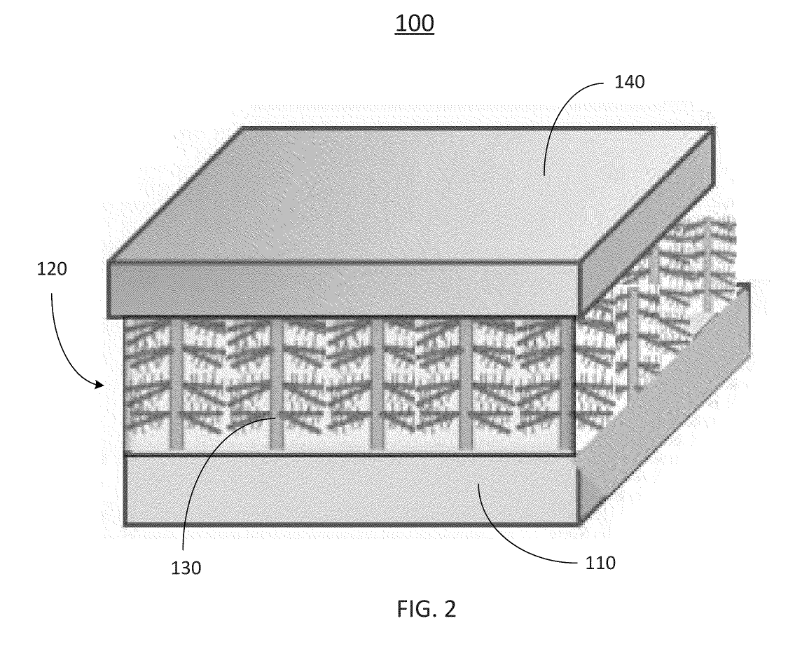

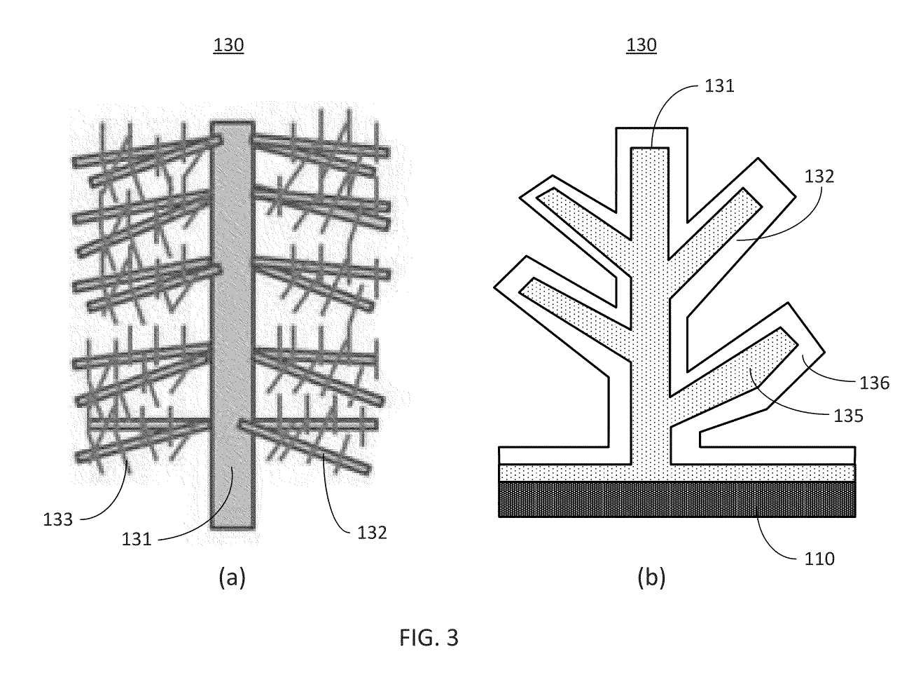

Referring to FIGS. 1-8, and particularly in FIGS. 1 and 2, in one embodiment of the invention, a photovoltaic (PV) cell 100 comprises 3D nanostructures 120, such as nanotrees and/or nanobushes 130, formed on a substrate 110 with necessary an optical window and charge collection electrodes 140. The 3D nanostructures 120 are similar to natural plants with numerous branches and subbranches. As shown in FIG. 3, each nanotree or nanobush 130 has a plurality of branches 132 and subbranches 133 grown from the plurality of braches 132. Each branch 132 of the nanotrees 130 is formed of semiconductor materials with core/shell structures for photon energy harvesting and conversion into electricity. In this example, each nanotree or nanobush 130 also has one (or more) trunk 131 from which the plurality of branches132 grows. All the trunk 131, the branches 132 and the subbranches 133 are formed with a core-shell structure having a core 135 and a shell 136 formed on and covering the core 135, as shown in FIGS. 3b, 5, 6 and 8. The core 135 and shell 136 of the core-shell structure are formed of the same or different semiconductor or metal materials.

In the exemplary embodiment shown in FIG. 6, the core-shell structure comprises a core 135, a first shell 136 formed on and covering the core 135, and a second shell 137 formed on and covering the first shell 137. The core 135 is formed of a metal or semiconductor as a support backbone, the first shell 136 is formed of a p-type or an n-type semiconductor and the second shell 137 is formed of an n-type or a p-type semiconductor so that a p-n junction is formed between the first shell 136 and the second shell 137.

In one embodiment, the substrate 110 is formed of an electrically conductive material, and is transparent to light. The photovoltaic cell also has an electrode 140 formed of an electrically conductive material on the nanostructures 120 such that the nanostructures 120 are located between the substrate 110 and the electrode 140. One of the substrate and the electrode is adapted as a back contact, while the other of the substrate and the electrode is used as a front window on which light is incident. The front window is a transparent to the incident light.

Accordingly, the 3D nanostructures 130 have a large p-n junction interface area, which enables the PV cell 100 to maximize the light confinement for absorption and the surface area for charge separation, and increase the charge collection efficiency by using highly conductive materials for the core structure, thereby, improving the cell efficiency of energy conversion from light to electricity or from electricity to light. Due to the economic processes for making such 3D nanostructures and the use of cheap materials, PV cells that are based on the 3D nanostructures are expected to have low cost and high efficiency for energy conversions from light to electricity or from electricity to light.

In one aspect, this invention relates to a method of fabrication of core-shell hierarchical nanostructures. In one embodiment, the method comprises the steps of growing nanowires on a substrate to form a core of the core-shell structure for defining the array of 3D nanotrees or nanobushes thereon; and coating a first thin layer on the core of the core-shell structure to form a shell of the core-shell structure. The growing step can be performed by electrochemical deposition in solution, and the coating step can be performed by chemical vapor deposition, atomic layer deposition, electrochemical deposition, or the like. In addition, the method may also include the step of coating a second thin layer on the thin layer first thin layer to form a double shell of the core-shell structure. The core is formed of a metal or semiconductor as a support backbone, the first shell is formed of a p-type or an n-type semiconductor and the second shell is formed of an n-type or a p-type semiconductor so that a p-n junction is formed between the first shell and the second shell. In one embodiment, the method further includes the step of coating one or more thin layers on the first thin layer to form multiple shells of the core-shell structure, wherein the core is formed of a metal or semiconductor as a support backbone, the first thin layer and the one or more thin layers are formed of different semiconductors such that a p-n junction is formed at an interface between any two adjacent thin layers.

The core-shell nanostructures have potential applications not only in PV cells, but also in sensitive sensors and detectors. In one embodiment, the PV cell structure contains a conductive and transparent PV cell window, on the top of which is the 3D core-shell nanostructures, and on the back side is an electrical contact. The nanostructures include nanotree or nanobush arrays with core-shell structures in their branches. Similar to natural plants, each nanotree has a main trunk and numerous branches and sub-branches which form different layers for light confinement and absorption. The trunk, the branches, and the sub-branches are all core-shell structures of semiconductor materials.

The core and shell of the core-shell structures are made of the same or different semiconductor or metal materials. The diameter of the core is around tens to hundreds nanometers and the thickness of the shell is about from a few nanometers to hundred nanometers. The height of the nanotree is about a few micrometers to tens or hundreds micrometers. The core material is highly conductive metal or semicondcutors. The shell may be metal, semiconductor, or polymer (organic) materials. The core-shell nanostructures have extremely high surface and interface area that are used in various devices such as dye-sensitized PV cells, p-n junction PV cells, gas/chemical sensors, and detectors.

For the dye-sensitized PV cells, the shell is active materials with superior photochemical and sensing properties and the core is a highly conductive material for charge transfer and collection. The hierarchical structures help improve the efficiency through an extremely large surface area, light confinement, and efficient charge collection of the nano-core structures.

For the p-n junction PV cells, the core material is an n-type wide band semiconductor while the shell is a p-type organic or inorganic thin layer for visible and near IR light absorption. Instead of a single shell, a double shell structure is also employed. In this case, the core is metal or semiconductor as a support backbone while the p-n junction is formed between the two shell semiconductors. Furthermore, a multi-shell structure can also be utilized to practice the invention, where the core is formed of a metal or semiconductor as a support backbone, while the multi-shell thin layers are formed of different semiconductors such that a p-n junction is formed at an interface between any two adjacent thin layer shells. The very thin shell ensures all the excited excitons reach the interface to generate electricity before recombination. This property is especially important for semiconductors with short exciton life times, such as organic materials. The weak absorption of individual thin shells is enhanced by the light confinement effect of the multi-layer branches.

Although a wide variety of materials may be chosen to build the hierarchical nanostructures, it is important to consider which one is practically feasible at low cost. One of the potential processes is electrochemical deposition in solution, which is considered as one of the least expensive and most flexible approaches for the large scale deposition of PV grade semiconductors. In one embodiment, the metal oxide hierarchical nanotrees are synthesized on glass or polymer substrates.

Among different approaches, chemical vapor deposition, atomic layer deposition and electrochemical deposition are the promising processes for shell coating. The precursors are able to reach the 3D hierarchical nanostructure surfaces. The shell materials include a variety of semiconductors, such as materials TiO2, Si, CdS, CdTe, CIGS, and the likes. Optimization of the deposition process, structural and property characterization, and post-growth treatments are investigated to improve the quality of the nanostructures. The challenge for device fabrication is the top contact on the shell layer. In one embodiment, metal thin films are evaporated on the top of the core-shell structure to serve as a back contact. Double shells of the core-shell structure may include n-Si/p-Si, n-CdS/p-CdTe, n-CIGS/p-CIGS, etc.

For such unique 3D hierarchical nanostructures, they have high absorption, high junction area, and efficient charge collection, all of which help increase PV cell efficiency. The material used for the backbone can be metal oxide, such as ZnO, which is economically available in a large scale. The shell material for p-n junction cells can be selected among various materials for PV cells. The quantity of material used in the hierarchical nanostructures is minimized due to very thin shell coatings, which further reduces the material costs. In addition, the low temperature electrochemical deposition enables economic production. No expensive fabrication is involved in any step of the processes. High quality nanostructures and prototype PV cells of high efficiency are expected using the structure. According to the invention, the 3D hierarchical core-shell nanostructures have wide impact on the commercialization of high-efficiency and low-cost photovoltaic devices and sensors/detectors. The approach to the 3D hierarchical core-shell nanostructures is suitable for many semiconductor materials. The structures reduce the quantity and quality of material necessary to approach high efficiency, allowing for substantial cost reductions. It also allows for the fabrication of complex devices directly on low- cost substrates and electrodes such as metal foil, glass, and inexpensive plastics, addressing another major cost in current photovoltaic technology.

In another aspect of the invention, a PV cell comprises two-dimensional (2D) or 3D metallic or semiconductor NW arrays of core-shell structures embedded in thin films of semiconductors. The outer shells of the NWs are either n-type or p-type and the films are p-type or n-type so that the p-n junctions are formed between the NWs and the thin films. The inner shell or NW core is highly conductive for charge collection. Due to the large surface area of the nanowires, a large p-n junction area is achieved, thereby improving the PV cell efficiency. In addition, the NWs have different shells that have different functions in the PV cells. Among other things, the advantages of the NW arrays of core-shell structures include high efficiency for charge collection, NW light trapping for enhanced light absorption, and large junction area for efficient charge separation, which help improve the energy conversion efficiency of the PV cell.

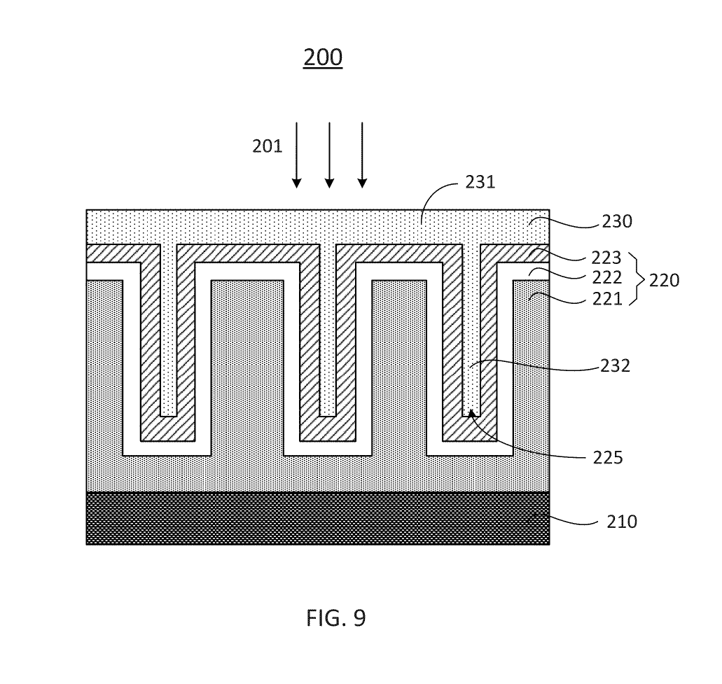

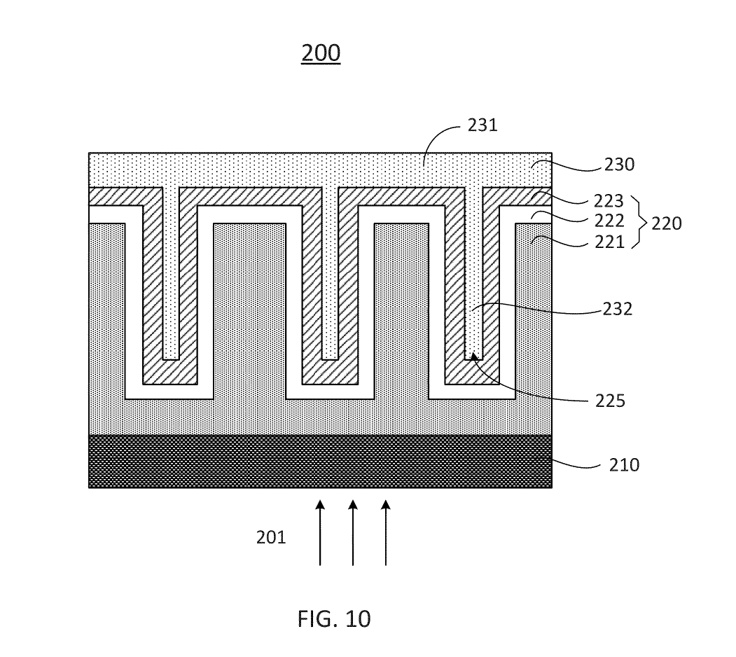

Referring to FIGS. 9 and 10, a photovoltaic cell 200 is shown according to one embodiment of the invention. The photovoltaic cell 200 has a substrate 210; at least one thin film 220 formed on the substrate 210, and an electrode 230 formed of nanowires on the at least one thin film 220. The at least one thin film 220 defines a plurality of recesses 225 therein, such that the electrode 230 has a thin layer 231 and an nanowire array 232 extending from the thin layer 231 into the plurality of recesses 225 of the at least one thin film 220.

The nanowire array 232 includes a core-shell structure having a core and at least one shell formed on and covering the core. In one embodiment, the outer shell of the core-shell structure of the nanowire array 232 is formed of an n-type or a p-type semiconductor, while the at least one thin film 220 is formed of a p-type or an n-type semiconductor, so that the outer shell of the core-shell structure of the nanowire array 232 and the at least one thin film 220 define a p-n junction therebetween.

In the embodiment shown in FIGS. 9 and 10, the at least one thin film 220 comprises a first thin film 221 and a second thin film 222 stacked on the substrate 210.

The second thin film 222 is formed of a p-type or an n-type semiconductor, so that the outer shell of the core-shell structure of the nanowire array 232 and the second thin film 222 define a p-n junction therebetween. Furthermore, the at least one thin film 222 also has a buffer film 223 formed on the second thin film 222. In one embodiment, the at least one thin film is formed to be a semiconductor light absorber.

As such, the core of the core-shell structure of the nanowire array 232 is formed of a substantially high conductive material for charge collection.

The photovoltaic cell 200 shown in FIG. 9 is structurally the same as that shown in FIG. 10. However, as shown in FIG. 9, the substrate 210 is corresponding to a back contact, while the electrode 230 is corresponding to a front window on which the light 201 is incident. As shown in FIG. 10, the substrate 210 is corresponding to a front window on which the light 201 is incident, while the electrode 230 is corresponding to a back contact.

According to the invention, the p-n junction is formed between the nanowires 232 and the films 220. The films 220 absorb sun light and generate electron-hole pairs. These pairs are separated at the p-n junction and produce electrons and holes. These charges are collected by contacts through the nanowires and the film to produce electricity. For such a design, it ensures that the charge separation and collection take place in different materials of core-shell structures, which has the advantage of tuning the material properties separately to achieve high charge separation and high charge collection, and therefore high PV cell efficiency.

In one embodiment, in order to reduce the fabrication cost, cheap materials and economic fabrication processes are utilized to make the PV cells. The improved efficiency and reduced fabrication cost ensure that cost-per-watt can be significantly reduced in the invented PV cell. In some embodiments, for fabricating PV cells, various thin films are used to replace the crystalline Si. Of them are chalcogenide thin films that very important in PV cell applications. Particularly, Cu(In₁₋ₓGaₓ)S₂ (CIGS) and CdTe are developed to a performance level close to that of silicon. The CIGS and CdTe thin films not only reach a high efficiency of 20%, but also possess more scalable processes as compared to Si. In one embodiment, the CIGS and CdTe thin films are directly deposited on large-area, low-cost substrates such as glass, metal, or plastic foil. Recently, an emerging compound semiconductor Cu₂ZnSnS₄ (CZTS) made of abundant natural materials has also attracted much attention in the PV technology. An efficiency of 11.1% has been achieved recently. Thus, continuing to improve the efficiency and fabrication technologies results in the availability of environmentally-friendly PV cells with low-cost and high-throughput industrial manufacturing.

In yet another aspect of the invention, a PV cell includes NW core-shell arrays embedded in a semiconductor light absorber, such as CIGS, CZTS, CdS, CdTe, and others. Due to the large p-n junction area, high charge collection efficiency, and enhanced light absorption, the PV cell has high efficiency of energy conversions. In addition, a low cost fabrication process is also utilized to achieve low cost devices. The invented NW core-shell structure is distinguished from those reported in literatures. Most current NW PV cells use the NW core as an active semiconductor (either n-type or p-type) as well as charge collection electrodes. However, the requirement for an n-type or p-type active semiconductor to form an optimal p-n junction is drastically different from that for charge collection which needs conductivity as high as possible. This may not be an issue in a conventionally planar structure because charge transports are achieved through the whole thin film. However, it becomes a serious issue in NW PV cells when the charge collection is performed through the narrow channels of individual NWs. This problem along with other factors causes the low efficiency reported in NW PV cells compared with their planar structures.

In the NW PV cell according to the invention, the role of the highly conductive NW cores or inner shells is solely for charge collection. The NW outer shells act as an n-type or p-type semiconductor to form p-n junctions with the p-type or n-type thin film such as a CIGS or CZTS film. For such a design, not only all the generated charge carriers can reach the p-n junction for separation, but also the high efficient charge collection can be achieved through the highly conductive NW cores or inner shell. Although the example materials are CIGS and CZTS as a light absorber, other materials, such as Si, can also be utilized to practice the invention. In one embodiment, the NW PV cell includes multi-shell layers, and the Si NW core is highly doped to achieve a high conductivity for charge collection. The shell layers with an optimal doping type and level form p-n junctions for charge separation.

In one embodiment, a solution based process to deposit p-type Cu₂O thin films for embedding ZnO nanowires is disclosed, which shows that the Cu₂O fills the narrow spaces between the ZnO NWs to form NW heterojunctions. This is an advantage of electrodeposition over most vapor-phase techniques which are typically incapable of filling the deep inter-wire voids. Photovoltaic effects of Cu₂O/ZnO NW radial junctions were measured. The short circuit current density of the NW junctions was is almost two times larger than that obtained from the planar junctions. The increased short circuit current of NW junctions is attributed to the increased p-n junction area in the NW structures.

In one embodiment, embedded NWs in thin films are also used in organicinorganic hybrid PV cells, i.e., embedding inorganic NWs in various organic polymers. The exciton lifetime in organic materials is usually small. Therefore, the NWs that protrude into the polymer absorbers are expected to help charge collection. In order to further improve the charge separation and collection at the interfaces, NW surface modification by other organic molecules has also been employed.

In one aspect, the invention relates to a photovoltaic device comprising one or more photovoltaic cells as disclosed above.

According to the invention, the 3D hierarchical nanostructures have all the advantages that NW PV cells have, including reduced reflection, light trapping capability, improved band gap tuning, and increased defect tolerance. These benefits are expected to reduce the quantity and quality of material necessary to approach high efficiency, allowing for substantial cost reductions. They also have superior features for PV cell applications as listed below: (1) much higher light trapping capability as compared with nanowire arrays which have already shown a light trapping effect—the nanotrees will work much better due to their geometrical structures; (2) extremely high junction (interface) area due to the multilayered branches and sub-branches—this will ensure high efficiency of charge separation; (3) high charge collection efficiency because each branch is directly grown onto the trunk which is a highly conductive material; and (4) maximized use of excited excitons for electricity due to the ultra-thin shell layer which allows excitons to reach the junction before recombination, even for those of very short lifetime.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### REFERENCE LIST

[1] “An Assessment of Solar Energy Conversion Technologies and Research Opportunities”, Report, GCEP Stanford University, 2006. http://gcep.stanford.edu
[2] L. Tsakalakos, “Nanostructures for photovoltaics”, Mater. Sci. Eng. R 62, 175-189 (2008).
[3] E. C. Garnett, M. L. Brongersma, Y. Cui, and M. D. McGehee, Annu Rev. Mater. Res. 41, 1-27 (2011).
[4] K. Wang, J. J. Chen, Z. M. Zeng, et al. “Synthesis and photovoltaic effect of vertically aligned ZnO/ZnS core/shell nanowire arrays”, Appl. Phys. Lett. 96, 123105 (2010).
[5] Z. Fan, H. Razavi, J. Do, et al. “Three-dimensional nanopillar-array photovoltaics on low-cost and flexible substrates”, Nature Mater. 8, 648-653(2010).
[6] J. B. Cui and U.J. Gibson, “A simple two-step electrodeposition of Cu₂O/ZnO nanopillar solar cells”, J. Phys. Chem. C114, 6408-6412 (2010).
[7] L. Greene, M. Law, B. Yuhas, P. Yang, “ZnO—TiO2 core-shell nanorod/P3HT solar cells”, J. Phys. Chem. C 111(50), 18451-18456 (2007).
[8] Y. Dong, B. Tian, T. J. Kempa, C. M. Lieber, “Coaxial group III-nitride nanowire photovoltaics”, Nano Lett. 9, 2183-2187 (2009).
[9] S. H. Ko, D. Lee, H. W. Kang, et al. “ Nanoforest of Hydrothermally Grown Hierarchical ZnO Nanowires for a High Efficiency Dye-Sensitized Solar Cell”, Nano Letters, in press, 2011.
[10] H. Cheng, W. Chiu, C. Lee, S. Tsai, W. Hsieh, “Formation of Branched ZnO Nanowires from Solvothermal Method and Dye-Sensitized Solar Cells Applications” J. Phys. Chem. C 112, 16359-16364 (2008).
[11] D. G. Diso, G. E. A. Muftah, V. Patel, and I. M. Dharmadasa,” Growth of CdS Layers to Develop All- Electrodeposited CdS/CdTe Thin-Film Solar Cells“, J. Electrochem. Soc. 157, H647-H651 (2010).
[12] P. C. Eklund, et al., Hydrogen storage material based on platelets and/or a multilayered core/shell structure, US Patent Publication No. 20050074612, Apr. 7, 2005.
[13] T. Shoji, et al., Method of producing core/shell composite nano-particles, US Patent Publication No. 20100215851, Aug. 26, 2010.
[14] W. K Choi, et al., Solar cell device comprising a consolidated core/shell polymer-quantum dot composite and method of the preparation thereof, US Patent Publication No. 20100294355, Nov. 25, 2010.
[15] S. C. Park, et al. Photoreceptive layer comprising metal oxide of core-shell structure and solar cell using the same, US Patent Publication No. 20060180193, Aug. 17, 2006.
[16] J. Ohlsson, et al. Optoelectronic semiconductor device, US Patent Publication No. 20100006817, Jan. 14, 2010.

What is claimed is:

1. A photovoltaic (PV) cell, comprising:
nanostructures formed of nanowires on a substrate.

2. The photovoltaic cell of claim 1, wherein the nanostructures comprise three dimensional (3D) nanotrees or nanobushes.

3. The photovoltaic cell of claim 2, wherein each nanotree or nanobush has a plurality of branches and a plurality of subbranches grown from the plurality of braches.

4. The photovoltaic cell of claim 3, wherein each nanotree or nanobush has one or more trunks from which the plurality of branches grows.

5. The photovoltaic cell of claim 4, wherein all the one or more trunks, the plurality of branches and the plurality of subbranches are formed with a core-shell structure.

6. The photovoltaic cell of claim 5, wherein the core-shell structure comprises a core and a shell formed on and covering the core.

7. The photovoltaic cell of claim 6, wherein the diameter of the core of the core-shell structure is around tens to hundreds nanometers, and the thickness of the shell of the core-shell structure is about from a few nanometers to hundred nanometers.

8. The photovoltaic cell of claim 6, wherein the core and shell of the core-shell structure are formed of the same or different semiconductor or metal materials.

9. The photovoltaic cell of claim 8, wherein the core o f the core-shell structure is formed of a highly conductive metal or semiconductor, and the shell o f the core-shell structure is formed of a metal, semiconductor, or polymer, such that the core-shell structure has substantially large surface and interface area for photon energy harvesting and conversion into electricity.

10. The photovoltaic cell of claim 8, wherein the shell o f the core-shell structure is formed of active materials with superior photochemical and sensing properties, and the core of the core-shell structure is formed of a highly conductive material for charge transfer and collection.

11. The photovoltaic cell of claim 8, wherein the core o f the core-shell structure is formed of an n-type wideband semiconductor, and the shell is formed of a p-type organic or inorganic thin layer for visible and near IR light absorption.

12. The photovoltaic cell of claim 8, wherein the shell is formed of a semiconductor including TiO2, Si, CdS, CdTe, CIGS, or the like.

13. The photovoltaic cell of claim 5, wherein the core-shell structure further comprises a core, a first shell formed on and covering the core, and a second shell formed on and covering the first shell, wherein the core is formed of a metal or semiconductor as a support backbone, the first shell is formed of a p-type or an n-type semiconductor and the second shell is formed of an n-type or a p-type semiconductor so that a p-n junction is formed between the first shell and the second shell.

14. The photovoltaic cell of claim 13, wherein the first/second shells comprises n-Si/p-Si, n-CdS/p-CdTe, n-CdS/p-CIGS, or the like.

15. The photovoltaic cell of claim 2, wherein the height of the nanotrees or nanobushes is about a few micrometers to tens or hundreds micrometers.

16. The photovoltaic cell of claim 1, wherein the substrate is formed of an electrically conductive material.

17. The photovoltaic cell of claim 1, wherein the substrate is transparent to light.

18. The photovoltaic cell of claim 1, further comprising an electrode formed of an electrically conductive material on the nanostructures such that the nanostructures are located between the substrate and the electrode.

19. The photovoltaic device, comprising one or more photovoltaic cells as claimed in claim 1.

20. A method for making a photovoltaic cell having an array of three dimensional (3D) nanotrees or nanobushes with a core-shell structure, comprising:
growing nanowires on a substrate to form a core of the core-shell structure for defining the array of 3D nanotrees or nanobushes thereon; and
coating a first thin layer on the core of the core-shell structure to form a shell of the core-shell structure.

21. The method of claim 20, wherein the growing step is performed by electrochemical deposition in solution.

22. The method of claim 20, wherein the coating step is performed by chemical vapor deposition, atomic layer deposition, electrochemical deposition, or the like.

23. The method of claim 20, wherein each nanotree or nanobush has a plurality of branches and a plurality of subbranches grown from the plurality of braches.

24. The method of claim 23, wherein each nanotree or nanobush has one or more trunks from which the plurality of branches grows.

25. The method of claim 20, wherein the core and shell of the core-shell structure are formed of the same or different semiconductor or metal materials.

26. The method of claim 25, wherein the core o f the core-shell structure is formed of a highly conductive metal or semiconductor, and the shell o f the core-shell structure is formed of a metal, semiconductor, or polymer, such that the core-shell structure has substantially large surface and interface area for photon energy harvesting and conversion into electricity.

27. The method of claim 25, wherein the shell o f the core-shell structure is formed of active materials with superior photochemical and sensing properties, and the core o f the core-shell structure is formed of a highly conductive material for charge transfer and collection.

28. The method of claim 25, wherein the core o f the core-shell structure is formed of an n-type wideband semiconductor, and the shell is formed of a p-type organic or inorganic thin layer for visible and near IR light absorption.

29. The method of claim 20, further comprising:
coating a second thin layer on the thin layer first thin layer to form a double shell of the core-shell structure, wherein the core is formed of a metal or semiconductor as a support backbone, the first shell is formed of a p-type or an n-type semiconductor and the second shell is formed of an n-type or a p-type semiconductor so that a p-n junction is formed between the first shell and the second shell.

30. The method of claim 20, further comprising:
coating one or more thin layers on the first thin layer to form multiple shells of the core-shell structure, wherein the core is formed of a metal or semiconductor as a support backbone, the first thin layer and the one or more thin layers are formed of different semiconductors such that a p-n junction is formed at an interface between any two adjacent thin layers.

31. A photovoltaic cell, comprising:
a substrate;
at least one thin film formed on the substrate, wherein the at least one thin film defines a plurality of recesses therein; and
an electrode formed of nanowires on the at least one thin film such that the electrode has a thin layer and an nanowire array extending from the thin layer into the plurality of recesses of the at least one thin film.

32. The photovoltaic cell of claim 31, wherein the nanowire array comprises a core-shell structure having a core and at least one shell formed on and covering the core.

33. The photovoltaic cell of claim 32, wherein the outer shell of the core-shell structure of the nanowire array is formed of an n-type or a p-type semiconductor.

34. The photovoltaic cell of claim 32, wherein the at least one thin film is formed of a p-type or an n-type semiconductor, so that the outer shell of the core-shell structure of the nanowire array and the at least one thin film define a p-n junction therebetween.

35. The photovoltaic cell of claim 32, wherein the at least one thin film comprises a first thin film and a second thin film stacked on the substrate, wherein the second thin film is formed of a p-type or an n-type semiconductor, so that the outer shell of the core-shell structure of the nanowire array and the second thin film define a p-n junction therebetween.

36. The photovoltaic cell of claim 35, wherein the at least one thin film further comprises a buffer film formed on the second thin film.

37. The photovoltaic cell of claim 32, wherein the core of the core-shell structure of the nanowire array is formed of a substantially high conductive material for charge collection.

38. The photovoltaic cell of claim 32, wherein the at least one thin film is formed to be a semiconductor light absorber.

39. The photovoltaic cell of claim 32, wherein the at least one thin film is formed of be a p-type or an n-type CIGS, CZTS, CdS, CdTe, Cu₂O, Si, or the like.

40. The photovoltaic device, comprising one or more photovoltaic cells as claimed in claim 30.
